(19) United States
(12) Patent Application Publication
(10) Pub. No.: US 2022/0320374 A1
(43) Pub. Date: Oct. 6, 2022

(54) MICRO LIGHT EMITTING ELEMENT, GROWTH SUBSTRATE, AND IMAGE DISPLAY ELEMENT

(71) Applicant: Sharp Fukuyama Laser Co., Ltd., Fukuyama City (JP)

(72) Inventors: Katsuji IGUCHI, Hiroshima (JP); Yuta IKAWA, Hiroshima (JP); Hidenori KAWANISHI, Hiroshima (JP)

(21) Appl. No.: 17/704,586

(22) Filed: Mar. 25, 2022

(30) Foreign Application Priority Data
Apr. 5, 2021 (JP) 2021-064341

(51) Int. Cl. H01L 33/32; H01L 33/20; H01L 27/15; H01L 33/38

(52) U.S. Cl. CPC H01L 33/32; H01L 33/20; H01L 27/156; H01L 33/382

(57) ABSTRACT

A micro light emitting element includes: a nitride semiconductor layer in which an N-type layer, a light emitting layer, and a P-type layer are stacked. Viewing in a direction perpendicular to a surface of the nitride semiconductor layer, multiple V pits are arranged at positions corresponding to vertexes of a polygon in a one-to-one relation in a region of the nitride semiconductor layer.

### CROSS-REFERENCE TO RELATED APPLICATION

The present application claims priority from Japanese Patent Application Number 2021-064341, the content to which is hereby incorporated by reference into this application.

### BACKGROUND OF THE INVENTION

### 1. Field of the Invention

The present disclosure relates to a micro light emitting element, a growth substrate, and an image display element.

### 2. Description of the Related Art

There is known an image display element in which multiple micro light emitting elements constituting pixels are arranged on a backplane. According to the technique disclosed in U.S. Patent Application Publication No. 2018/0090058, for example, a micro light emitting diode (LED) array emitting visible light is arranged on a driving circuit backplane on which a driving circuit is formed.

The above-mentioned image display element has characteristics of high brightness and high durability while an element size is very small. Therefore, the above-mentioned image display element is expected as an image display element for use in glasses-like devices, head-up displays (HUDs), and so on.

When the image display element is assembled into the glasses-like devices, emitted light is to be efficiently taken into an optical system, and the light emitted from the image display element is to be suppressed from diverging. In U.S. Patent Application Publication No. 2018/0090058, divergence of the light released to the outside is suppressed by providing a reflector around the light emitting diode.

In the image display element for use in the glasses-like devices and the head-up displays, light distribution is to be controlled to concentrate the light emitted from a pixel toward the front side for the purpose of realizing bright display. Accordingly, a light distribution control element such as a reflector, a microlens, a photo-crystal, or an antenna element, for example, is used in combination with the micro light emitting element. From the viewpoint of causing such a light distribution control element to function efficiently, the micro light emitting element serving as a light source is to be made as small as possible. On the other hand, a pixel size is reduced with a demand of increasing resolution of the image display element. In trying to arrange both the micro light emitting element and the reflector in the reduced pixel size, the size of the micro light emitting element is to be made even smaller as compared with the pixel size. For example, if the pixel size is about 5 to 2 μm, a length of one side of the micro light emitting element is to be about 2.5 to 1 pm at most and is desired to be smaller than about 1 μm.

To realize, as described above, the micro light emitting element that is as small as a micron or sub-micron size, a nitride semiconductor, such as gallium nitride, forming the micro light emitting element is to be processed into a very small size. In a compound semiconductor such as a nitride semiconductor, however, defects are likely to occur in a processed surface, and light emission efficiency tends to reduce. Thus, a basic issue from the viewpoint of realizing the image display element with high resolution is to realize the micro light emitting element as small as possible without reducing the light emission efficiency.

It is desirable to realize a micro light emitting element that is very small and has high light emission efficiency.

### SUMMARY OF THE INVENTION

According to an aspect of the disclosure, there is provided a micro light emitting element including a nitride semiconductor layer in which an N-type layer, a light emitting layer, and a P-type layer are stacked. Viewing in a direction perpendicular to a surface of the nitride semiconductor layer, multiple V pits are arranged at positions corresponding to vertexes of a polygon in a one-to-one relation in a region of the nitride semiconductor layer.

According to an aspect of the disclosure, there is provided a growth substrate on which a nitride semiconductor layer is to be grown. Unit cells each including a protrusion array in which protrusions are arranged at positions corresponding to vertexes of a polygon are arranged in a two-dimensional array on a surface of the growth substrate.

According to an aspect of the disclosure, there is provided a manufacturing method of a micro light emitting element, the manufacturing method including growing a nitride semiconductor layer on a growth substrate and forming multiple mesa portions by removing parts of the nitride semiconductor layer. Unit cells each including a protrusion array in which protrusions are arranged at positions corresponding to vertexes of a polygon are arranged in a two-dimensional array on a surface of the growth substrate, and the mesa portions are each formed in a central region of the protrusion array.

### BRIEF DESCRIPTION OF THE DRAWINGS

FIG. 1 is a schematic sectional view of a micro light emitting element according to a first embodiment of the present disclosure;

FIG. 2 is a schematic plan view when viewed along a cross-section A-A in FIG. 1;

FIG. 3A is a schematic view illustrating a plan view layout of protrusion unit cells formed on a surface of a growth substrate that is used in manufacturing the micro light emitting element according to the first embodiment of the present disclosure;

FIG. 3B is a schematic view illustrating a plan view layout of V pits formed after growth of a nitride semiconductor layer;

FIG. 3C is a schematic view illustrating a plan view layout of protrusion unit cells according to a modification of the first embodiment;

FIG. 4 represents schematic sectional views illustrating manufacturing steps of the micro light emitting element according to the first embodiment;

FIG. 5 represents schematic sectional views illustrating manufacturing steps of the micro light emitting element according to the first embodiment;

FIG. 6 represents schematic sectional views illustrating manufacturing steps of the micro light emitting element according to the first embodiment;

FIG. 7 is a schematic sectional view of the nitride semiconductor layer in the manufacturing steps of the micro light emitting element according to the first embodiment;

FIG. 8 is a flowchart illustrating manufacturing steps of the micro light emitting element according to the first embodiment;

FIG. 9 is a schematic sectional view of a micro light emitting element according to a second embodiment of the present disclosure;

FIG. 10 represents schematic sectional views illustrating manufacturing steps of the micro light emitting element according to the second embodiment;

FIG. 11 represents schematic sectional views illustrating manufacturing steps of the micro light emitting element according to the second embodiment;

FIG. 12 represents schematic sectional views illustrating manufacturing steps of the micro light emitting element according to the second embodiment;

FIG. 13 is a graph indicating a brightness distribution of micro light emitting elements according to Example and a brightness distribution of micro light emitting elements according to Comparative Example;

FIG. 14A is a schematic sectional view of a nitride semiconductor layer in related art;

FIG. 14B illustrates, for the nitride semiconductor layer in the related art, a surface image obtained by observing a surface of a light emitting layer with an AFM (Atomic Force Microscope); and

FIG. 14C is a schematic plan view illustrating a layout of protrusions on a surface of a growth substrate in the related art.

### DETAILED DESCRIPTION OF THE INVENTION

A micro light emitting element according to a first embodiment of the present disclosure, which is used in an image display element, will be described below. First, an overall structure of the image display element is roughly explained. The image display element is in the form of a flat plate, and a pixel region where multiple micro light emitting elements are arranged is formed on a first surface side of the image display element. A driving circuit backplane is arranged on an opposite side to a first surface of the micro light emitting element. The driving circuit backplane supplies currents to the micro light emitting elements formed in the pixel region and controls emission of light. The micro light emitting elements are arranged on a first surface side of the driving circuit backplane, and the following description is made in connection with an example in which light is emitted to the first surface side. However, a direction of light emission is not limited to the first surface side.

The micro light emitting elements may be arranged in an array in the pixel region. The wording “arranged in an array” indicates that the micro light emitting elements are regularly arranged or are arranged in accordance with a predetermined rule. The micro light emitting elements emit light in a direction toward an opposite side to the driving circuit backplane. The emitted light is also called emission light. Unless otherwise specified, a surface of each of the micro light emitting elements from which the light is emitted is called a light emitting surface. In the following description of a structure of the image display element, unless otherwise specified, the light emitting surface is called an upper surface (first surface), a surface on an opposite side to the light emitting surface is called a lower surface (second surface), and surfaces on a lateral side other than the upper surface and the lower surface are called side surfaces. Those names are defined in a sectional view when looking at a cross-section perpendicular to the light emitting surface with the light emitting surface facing upward. Similarly, the direction of light emission is called an upward direction, and a direction opposite to the direction of light emission is called a downward direction. Moreover, a direction perpendicular to the light emitting surface and oriented toward air is also called front direction.

The micro light emitting element is a light emitting diode element including a nitride semiconductor layer. The micro light emitting element capable of emitting light over a wavelength band from ultraviolet to red can be realized with the nitride semiconductor layer.

The micro light emitting element includes an anode electrode and a cathode electrode and is connected to drive electrodes on a driving circuit backplane. Portions of the micro light emitting element, such as the electrodes and a protective film, other than the nitride semiconductor layer are not related directly to the present disclosure, and hence detailed description of those portions is omitted in the following in some cases.

In the driving circuit backplane, a micro light emitting element driving circuit controlling currents supplied to the individual micro light emitting elements is arranged in (or joined to) a region that is positioned to face the pixel region. Furthermore, in the driving circuit backplane, a row selection circuit selecting each row of the micro light emitting elements that are arranged in a two-dimensional matrix pattern, a column signal output circuit outputting a light emission signal to each column of the micro light emitting elements, an image processing circuit computing the light emission signal based on an input signal, input/output circuits, and so on are arranged outside the region that is positioned to face the pixel region. A P-drive electrode (second drive electrode) and an N-drive electrode (first drive electrode) both connected to the micro light emitting element are arranged on a surface of the driving circuit backplane on a joined surface side. The driving circuit backplane is generally a silicon substrate (semiconductor substrate) on which an LSI is formed, or a glass substrate or a plastic substrate on which TFTs (thin film transistors) are formed, and can be manufactured according to a known technique. Hence details of the function and structure of the driving circuit backplane are not described here.

The shape of the micro light emitting element when viewed in a direction perpendicular to the pixel region is not limited to a particular one. The micro light emitting element may have any suitable one of various shapes in a plan view, such as rectangular, polygonal, circular, and elliptic shapes. A maximum length (width) of the micro light emitting element when viewed in the direction perpendicular to the pixel region is about 5 μm or less in many cases, but the maximum length is not limited to such a value. Furthermore, the image display element is constituted by integrating three thousand or more micro light emitting elements in the pixel region in many cases, but the number of the integrated micro light emitting elements is not limited to those cases.

### Problem in Related Art

A problem in the related art will be described below to clarify the feature of this embodiment. Components in the related art corresponding to those in this embodiment are described by using the same reference signs attached to those components in this embodiment.

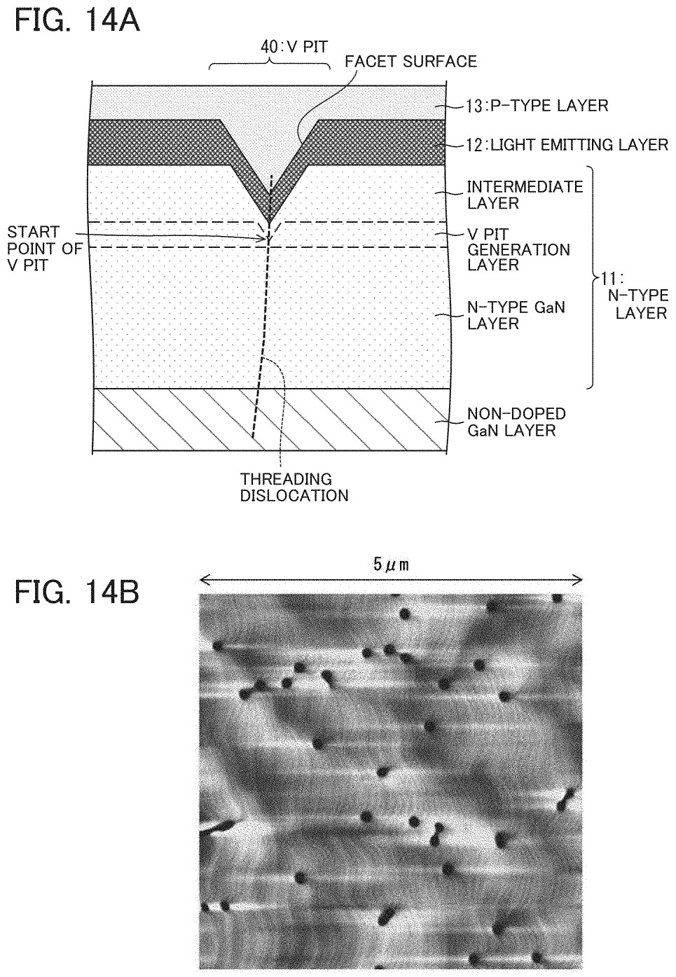

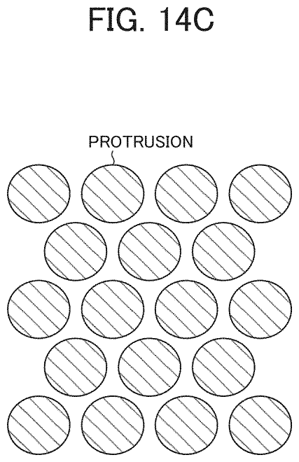

FIG. 14A is a schematic sectional view of a V pit 40 in a nitride semiconductor layer in the related art. A N-type GaN layer 11, a light emitting layer 12, and a P-type layer are sequentially laminated on a non-doped GaN layer formed on a growth substrate. A V pit is formed at an end of a threading dislocation and has a shape of reversed pyramid. A multilayer film of the same layer structure as that of the multiple quantum well layer is deposited on a facet surface of the V pit and the P-type layer 13 fills inside the V pit.

FIG. 14B illustrates, for the nitride semiconductor layer in the related art, a surface image that is obtained by stopping growth of the nitride semiconductor layer after growth of the light emitting layer 12, and by observing a surface of the light emitting layer with an AFM (Atomic Force Microscope). A portion appearing black represents an opening of the V pit. FIG. 14B represents the image obtained by observing a region of 5 μm square. From that image, a density of the V pits can be estimated to be 1.5E8 pits/cm² (1.5×10⁸ pits/cm²). A length (diameter) of the opening of the V pit in a stage at end of the growth of the light emitting layer 12 is desired to be about 100 nm to 300 nm. In either case in which the length (diameter) is greater or smaller than the above-mentioned range, light emission characteristics of the light emitting layer reduces. When the P-type layer 13 is grown, the opening (hole) of the V pit is filled, and a surface of the V pit is planarized. Although not seen from FIG. 14B, the shape in a plan view of the opening of the V pit is hexagonal in many cases. It is considered that the facet surface of the V pit is defined by a specific crystallographic surface of a nitride semiconductor.

A related-art manufacturing method can control, during growth of the nitride semiconductor layer, a position in a depth direction of an epitaxial layer at which formation of the V pit is to be started. However, the related-art manufacturing method is not able to control a position at which the V pit is to be generated in a horizontal direction. As illustrated in FIG. 14B, therefore, the positions at which the V pits are generated in a horizontal plane are at random. In other words, the related-art manufacturing method is not able to control how many V pits are included in the micro light emitting element, and at which positions in the micro light emitting element the V pits are formed. Accordingly, in the micro light emitting elements formed by the related-art method, a great variation occurs in the number of the V pits included in the micro light emitting elements and the positions of the V pits in a plane where the micro light emitting elements are formed. According to the related art, a planar density of the V pits is about 1E8 pits/cm² to 5E8 pits/cm². Thus, when an area of the light emitting layer of each micro light emitting element is 1 μm², one to five V pits in average are included in the micro light emitting element. Assuming, for example, that the V pits are distributed in accordance with the Poisson distribution with the planar density of 1E8 pits/cm², the number of the V pits included in one micro light emitting element (1 μm²) is 0 to 4 in many cases, and the larger number of the V pits may also be included in some cases.

Because the V pit does not include the light emitting layer formed as per intended, the V pit does not emit light, or intensity of light emission from the V pit is low. Accordingly, the above-described great variation in the number of the V pits included in the micro light emitting elements implies that light emission efficiencies of the micro light emitting elements vary greatly.

There is another variation factor for the light emission intensity that the V pit present in an outer peripheral portion of the light emitting layer of the micro light emitting element causes a smaller influence, while the V pit present in a central portion of the light emitting layer causes a greater influence. When a mesa portion of the micro light emitting element is processed, a processing damage occurs. Because of the light emission efficiency of the light emitting layer 12 in a peripheral region of the mesa portion being low, even when the V pit is present in the peripheral region of the mesa portion, the influence is small. However, the influence of the V pit present in a central region of the mesa portion upon the light emission efficiency is great. As mentioned above, the micro light emitting elements including the mesa portions as small as a micron size have the problem that a great variation may occur in the light emission efficiency due to randomness of the V pits.

By contrast, the embodiment of the present disclosure can reduce the variation in the light emission efficiency caused in the above-described micro light emitting elements of the related art. More specifically, because the V pit is generated dominantly due to threading dislocation existing in a nitride semiconductor layer 14, a micro light emitting element 100 according to this embodiment can be realized by controlling a position at which the threading dislocation is to be generated. A structure and a manufacturing method of the micro light emitting element 100 according to this embodiment will be described below with reference to the drawings.

### Structure of Micro Light Emitting Element 100

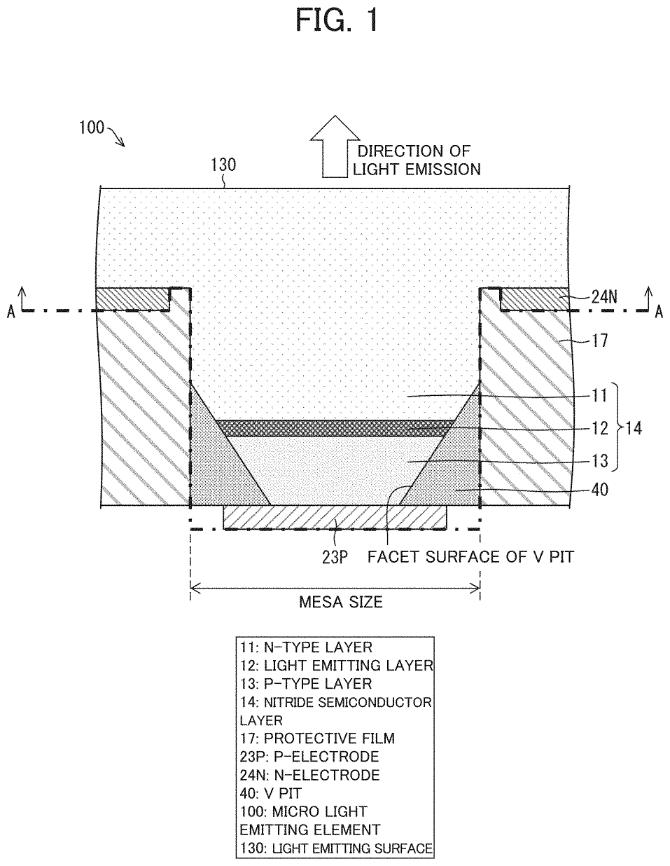

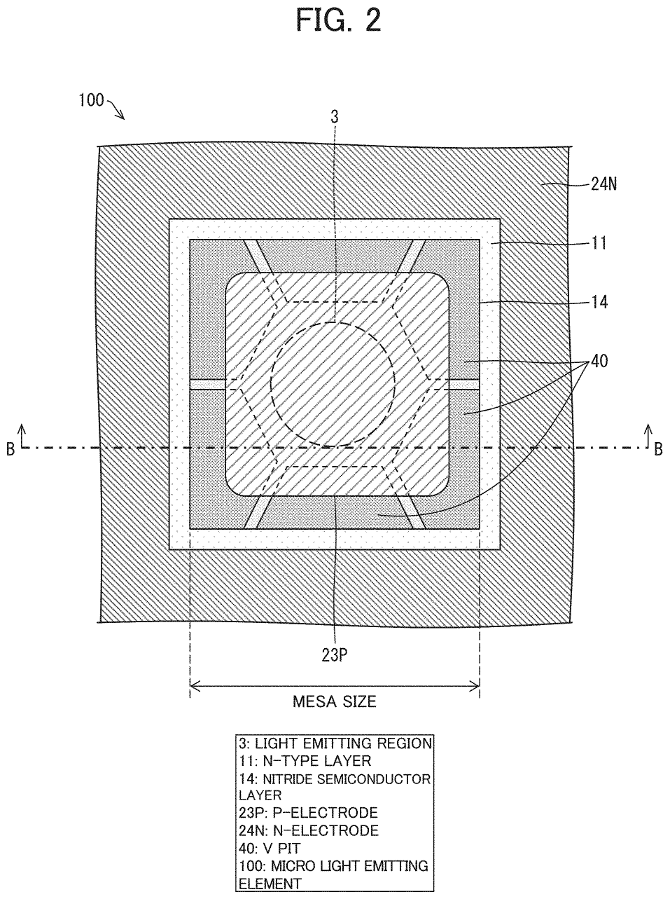

The structure of the micro light emitting element 100 according to the first embodiment will be described below with reference to FIGS. 1 and 2. FIG. 1 is a schematic sectional view of the micro light emitting element 100 according to the first embodiment. More specifically, FIG. 1 is a sectional view when viewed along a cross-section B-B in FIG. 2. FIG. 2 is a schematic plan view of the micro light emitting element 100 when viewed along a cross-section A-A (also called a horizontal cross-section) in FIG. 1, namely a schematic plan view when looking at the micro light emitting element 100 along the cross-section A-A in a stacking direction of the nitride semiconductor layer 14 (i.e., in a direction perpendicular to a surface of the nitride semiconductor layer 14). In the following description, viewing in the direction perpendicular to the surface of the nitride semiconductor layer 14 is also called “in a plan view”.

The micro light emitting element 100 includes the nitride semiconductor layer 14 in which an N-type layer 11, a light emitting layer 12, and a P-type layer 13 are stacked. Viewing in the direction perpendicular to the surface of the nitride semiconductor layer 14, multiple V pits 40 are arranged at positions corresponding to vertexes of a polygon in a one-to-one relation in a region of the nitride semiconductor layer 14. The micro light emitting element 100 includes an N-electrode 24N connected to the N-type layer 11 and a P-electrode 23P connected to the P-type layer 13. As illustrated in FIGS. 1 and 2, most part of side surfaces of the nitride semiconductor layer 14 on a side closer to the P-type layer 13 are surrounded by facet surfaces of the multiple V pits 40.

The above-mentioned region of the nitride semiconductor layer 14 is a region where, looking at one micro light emitting element 100 in the direction perpendicular to the surface of the nitride semiconductor layer 14, the N-type layer 11, the light emitting layer 12, and the P-type layer 13 are stacked in at least part of the nitride semiconductor layer 14. The above-mentioned region of the nitride semiconductor layer 14 is, for example, a region of a later-described mesa portion. However, all the V pits 40 are not arranged within the region of the nitride semiconductor layer 14 in some cases. For example, the multiple V pits 40 formed at the positions corresponding to the vertexes of the polygon may be partly removed by etching, for example, in a process of forming the micro light emitting element 100. It is difficult to exactly control the positions of the V pits 40. Thus, the wording “the V pits 40 are arranged at the positions corresponding to the vertexes of the polygon” indicates, for example, that, in a plan view, each of the vertexes of the polygon are present within opening of the corresponding V pits 40.

The polygon is desired to be an n-sided polygon with n≥6 (n: an integer). This is because, looking at the facet surfaces of the V pits 40 in a plan view, the facet surfaces tend to define the n-sided polygon with n≥6. In particular, looking at the facet surfaces of the V pits 40 in the plan view, the facet surfaces tend to define a regular hexagon. Therefore, the polygon is particularly desired to be the regular hexagon. By arranging the V pits 40 at the positions corresponding to the vertexes of the regular polygon, the light emitting layer 12 surrounded by six V pits 40 tends to define the regular hexagon in a plan view. In this embodiment, the polygon is the regular hexagon.

Viewing the light emitting layer 12 in the direction perpendicular to the surface of the nitride semiconductor layer 14, end portions of the light emitting layer 12 are in contact with the facet surface of the multiple V pits 40. Here, the wording “end portions of the light emitting layer 12” indicates end portions of the light emitting layer 12 on a side surface side in FIG. 1. As illustrated in FIG. 1, the end portions of the light emitting layer 12 on the side surface side are in contact with the facet surface of the V pits 40.

Moreover, viewing the light emitting layer 12 in the direction perpendicular to the surface of the nitride semiconductor layer 14, the facet surfaces with which the end portions of the light emitting layer 12 are in contact define a shape geometrically similar to a polygon. This polygon corresponds to, as described later, a layout shape of protrusions formed on a growth substrate on which the nitride semiconductor layer 14 is grown. As illustrated in FIGS. 1 and 2, the end portions of the light emitting layer 12 on the side surface side are in contact with the facet surfaces of the V pits 40. Viewing the light emitting layer 12 in a plan view, the facet surfaces in contact with those end portions define a shape geometrically similar to the layout shape of the protrusions formed on the growth substrate. In the example illustrated in FIGS. 1 and 2, horizontal end portions of the light emitting layer 12 are in contact with the facet surfaces of the six V pits 40, and the contact end portions define a hexagonal shape in a plan view. This hexagon is geometrically similar to the hexagon representing the layout shape of the protrusions formed on the growth substrate.

The V pit 40 is a V-shaped recess in cross-section which is generated in a stage of growing the N-type layer 11. As described above, the V pit 40 is generated mainly due to the threading dislocation. A surface of the recess defining the V pit 40 is formed as the facet surface specific to the V pit 40. In a next stage of growing the light emitting layer 12, the thin light emitting layer 12 is formed on the surface of the recess defining the V pit 40. In a next stage of growing the P-type layer 13, the P-type layer 13 is grown to fill the recess defining the V pit 40. A pyramidal recess formed during a growing process of the N-type layer 11 and the light emitting layer 12, including the P-type layer 13 as well filling the pyramidal recess, is called the V pit 40 in this embodiment.

The facet surface of the V pit 40 is a specific crystallographic surface that is formed when the nitride semiconductor layer 14 is grown, and it is different from a surface formed by processing, such as plasma etching, after formation of the nitride semiconductor layer 14.

In FIG. 1, a length of one side of the nitride semiconductor layer 14 including the light emitting layer 12 is called a mesa size. A length of the micro light emitting element 100 is represented by the mesa size. As illustrated in FIG. 2, when viewed from a side including the P-type layer 13, the multiple V pits 40 are arranged around the nitride semiconductor layer 14. In other words, any V pit 40 is not arranged in a central region of the nitride semiconductor layer 14.

Although, in the example illustrated in FIG. 2, the adjacent V pits 40 are not in contact with each other, they may contact each other. In the micro light emitting element 100, light is emitted from the light emitting layer 12 in a region (light emitting region 3) of a central portion on the side including the P-type layer 13 where any V pit 40 is not present.

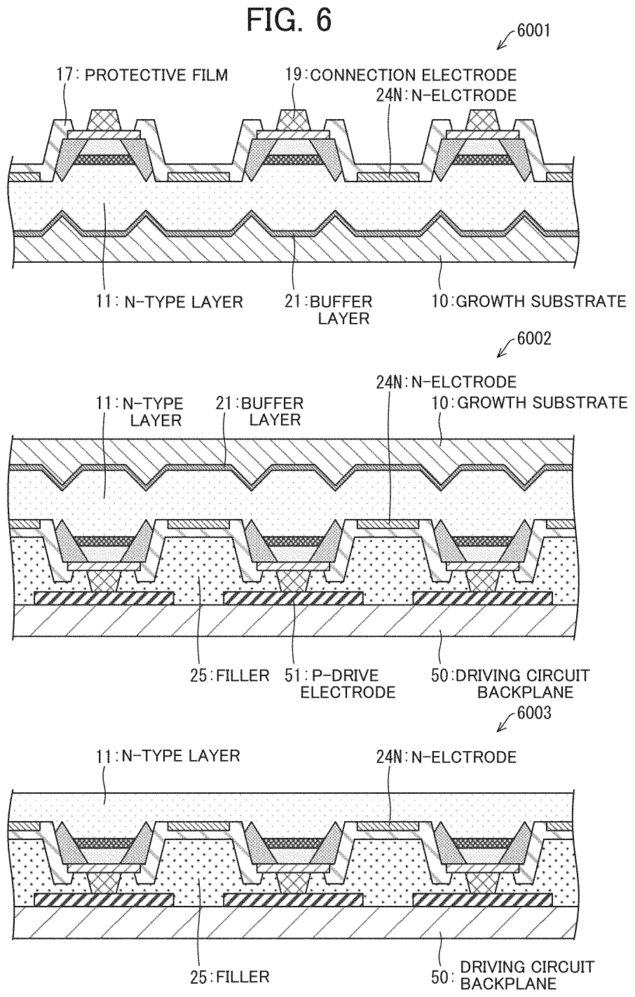

As illustrated in FIG. 2, the P-electrode 23P is formed over an area covering the light emitting region 3 when viewed from below. The P-electrode 23P may be formed over an area covering not only the light emitting region 3, but also at least parts of the V pits 40. In this embodiment, as illustrated in FIG. 1, the N-type layer 11 has a T shape, and the N-electrode 24N is arranged on a lower side of horizontally extending portion of the N-type layer 11 (on a side closer to the driving circuit backplane 50 (see FIG. 6)). The N-electrode 24N is desired to be a metal film with high reflectivity. In the example illustrated in FIG. 1, the N-type layer 11 is continuous between (or shared by) the micro light emitting elements 100 adjacent to each other, but it may be arranged independently for each of the micro light emitting elements 100.

In this embodiment, as illustrated in FIG. 2, for each of the micro light emitting elements 100, the six V pits 40 are arranged at the positions corresponding to the vertexes of the regular hexagon when viewed from below. The light emitting region 3 is positioned in a central region surrounded by the six V pits 40. By arranging the V pits 40 at the positions corresponding to the vertexes of a polygon as mentioned above, an area where any V pit 40 is not formed can be obtained in a central region of the polygon. The light emitting region 3 less likely to be affected by the V pits 40 can be formed by utilizing the area where any V pit 40 is not formed, as the primary light emitting region 3.

The polygon with the vertexes on which the V pits 40 are arranged is not limited to the hexagon and may be an n-sided polygon. Here, n is a four or greater integer and is more desirably six or greater. Furthermore, the polygon may be other than a regular polygon. From the viewpoint of forming the micro light emitting element as small as possible, however, the polygon is desired to be the regular polygon. Because the facet surfaces of the V pits 40 define a regular hexagon in the plan view as illustrated in FIG. 2, the polygon is desired to be a hexagon. The polygon is more desirably a regular hexagon. Thus, by arranging the V pits 40 at the positions corresponding to the vertexes of the regular hexagon, the area where any V pit 40 is not present can be formed in a central region of the regular hexagon.

### Advantageous Effects of Micro Light Emitting Element 100

With the micro light emitting element 100 according to this embodiment, as described above, viewing in the direction perpendicular to the surface of the nitride semiconductor layer 14, the multiple V pits 40 are arranged at the positions corresponding to the vertexes of the polygon (regular polygon in this embodiment) in a one-to-one relation in the region of the nitride semiconductor layer 14. Therefore, any V pit 40 is not formed in a central region of the light emitting layer 12. Since that central region where any V pit 40 is not formed can be utilized as the light emitting region 3, reduction in the light emission efficiency due to the V pits 40 can be suppressed. As a result, this embodiment can realize the micro light emitting element that is very small and has high light emission efficiency.

### Structure of Growth Substrate 10

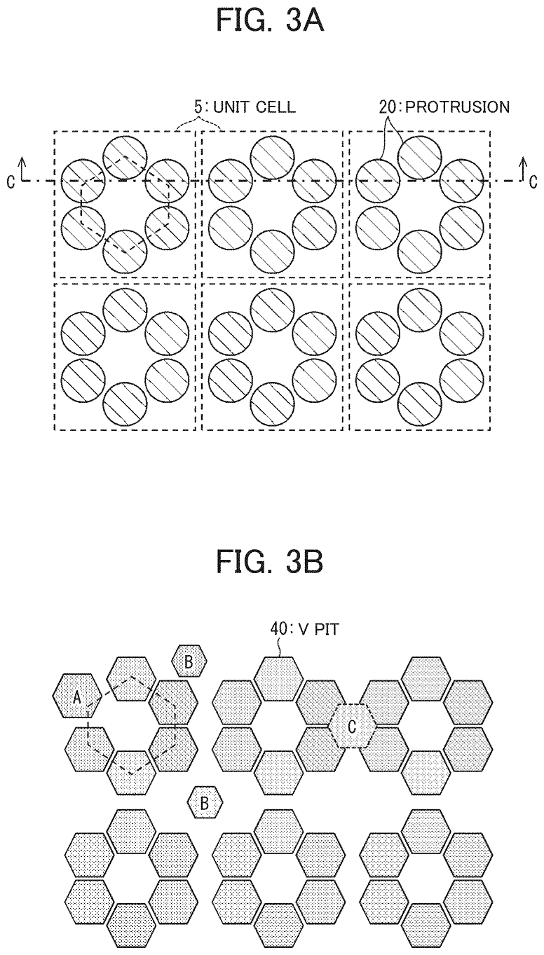

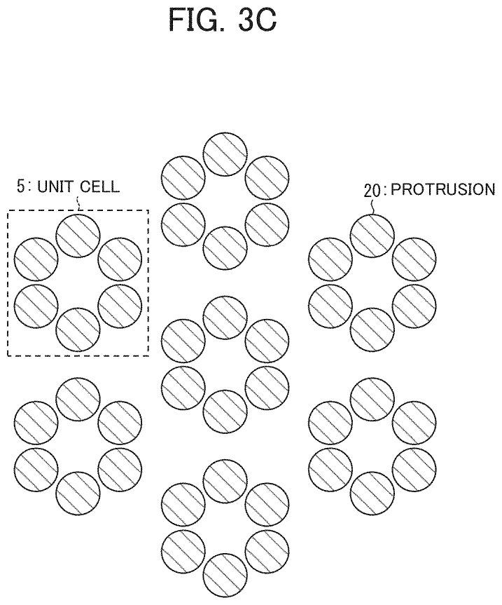

A structure of the growth substrate 10 on which the nitride semiconductor layer 14 of the micro light emitting element 100 according to this embodiment is to be grown and a manufacturing method of the micro light emitting element 100 will be described below with reference to FIGS. 3A to 3C and 4 to 6. First, the growth substrate 10 is described. FIGS. 3A and 3B are a schematic view illustrating a plan view layout of the protrusions formed on a surface of the growth substrate 10 and the V pits formed in the nitride semiconductor layer corresponding to the protrusions, respectively.

In this embodiment, as in the related art, a sapphire substrate (C surface) is used as the growth substrate 10. However, the structure of the growth substrate 10 is different from that in the related art. The growth substrate 10 includes protrusions 20 on its growth surface (also simply called a surface). More specifically, as illustrated in FIG. 3A, the protrusions 20 are arranged at positions corresponding to vertexes of a polygon. In the example illustrated in FIG. 3A, the polygon is a regular hexagon.

The above-described structure in which the protrusions 20 are arranged at the positions corresponding to the vertexes of the polygon is called one set of protrusion array. A region including the one set of protrusion array is called a unit cell 5. Multiple unit cells 5 are arranged in a two-dimensional array on the growth surface. In one example, as illustrated in FIG. 3A, the unit cells 5 can be arranged on the surface of the growth substrate 10 adjacent to each other in vertical and horizontal directions. A two-dimensional array pattern of the unit cells 5 is not limited to the example illustrated in FIG. 3A. In another example, as illustrated in FIG. 3C, the unit cells 5 may be arrayed such that the unit cells 5 are shifted every other row by a half length of one side of the unit cell 5. Furthermore, the protrusion array pattern is not limited to the regular hexagon and may be another polygon with a different number of vertexes.

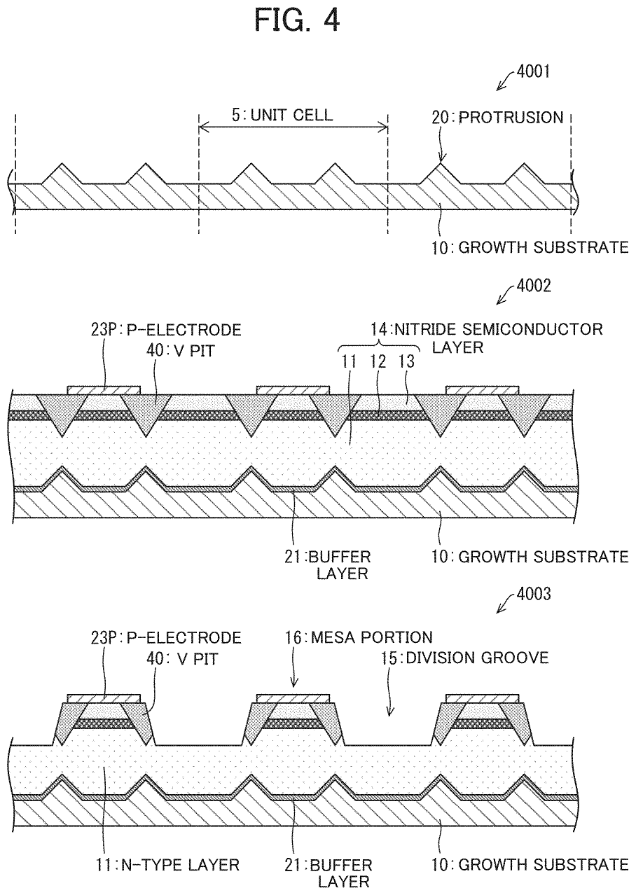

The unit cell 5 corresponds to one micro light emitting element 100. In other words, a central portion of each protrusion array serves as the light emitting region of the micro light emitting element 100. A sectional view taken along line C-C in FIG. 3A is illustrated in 4001 of FIG. 4. As illustrated in FIGS. 3A and 4 (4001), on the surface of the growth substrate 10 on which the nitride semiconductor layer is to be grown, the protrusion arrays each including the protrusions 20 arranged at the positions corresponding to the vertexes of the polygon (regular hexagon in this embodiment) are formed and the unit cells 5 including the protrusion arrays are arranged in the two-dimensional array. The polygon is desired to be an n-sided polygon with n≥6 (n: an integer) and is most desirably a regular hexagon.

The shape of each of the protrusions 20 is desired to be conical or truncated-conical. A lateral surface when viewing the conical or truncated-conical protrusion in cross-section is not limited to a linear shape and may be curved. A height of the protrusion 20 is desired to be about 3 μm or less. A distance between the protrusions 20 can be changed depending on the size of the micro light emitting element 100. The height of the protrusion 20 can also be changed depending on the distance between the protrusions 20. In this embodiment, the distance between the protrusions 20 is desired to be about 1 μm or less, and the height of the protrusion 20 is also desired to be about 1 μm or less. A distance between two protrusions 20 opposing to each other with a center of the unit cell 5 interposed therebetween is desired to be substantially equal to the size of a lower surface of the nitride semiconductor layer 14 illustrated in FIG. 1 (for example, the mesa size).

### Advantageous Effects of Growth Substrate 10

As described above, on the surface of the growth substrate 10 according to this embodiment, the unit cells 5 including the protrusion arrays in which the protrusions 20 are arranged at the positions corresponding to the vertexes of the polygon are arranged in the two-dimensional array. With such a structure, the nitride semiconductor layer 14 not including any V pit 40 formed therein can be grown in the central region of the light emitting layer 12. As a result, the micro light emitting element can be manufactured, which is very small and which has high light emission efficiency.

### Manufacturing Method of Micro Light Emitting Element 100

A manufacturing method of the micro light emitting element 100 will be described below. FIGS. 4 to 6 are sectional views illustrating manufacturing steps of the micro light emitting element 100 according to this embodiment. In the micro light emitting element 100, the V pits 40 are formed at the positions corresponding to the vertexes of the regular hexagon.

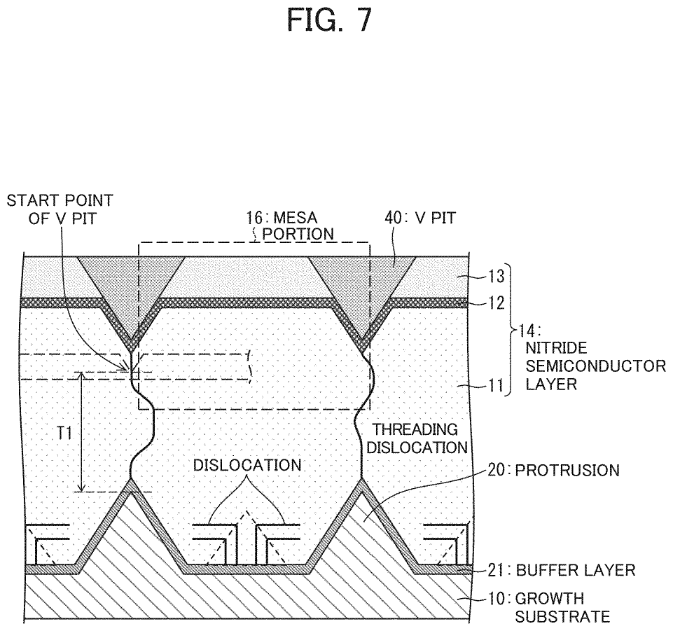

First, the nitride semiconductor layer 14 is grown on the growth substrate 10 illustrated in 4001 of FIG. 4. In more detail, as illustrated in FIG. 7, a buffer layer 21, a non-doped layer (not illustrated), and the N-type layer 11 are successively stacked on the surface of the growth substrate 10. This step is different from the related-art growth method in that, because the distance between the protrusions 20 is smaller and the height of the protrusion 20 is lower, overall thickness of the non-doped layer and the N-type layer is thinner than one of the related-art.

In an initial stage of the growth on the buffer layer 21, a film is hardly deposited on a slope of the protrusion 20, and a gallium nitride layer is selectively deposited on a flat portion. This brings about a state in which the protrusion 20 is surrounded by facet surfaces (denoted by oblique dashed lines in FIG. 7, the inside of the dashed lines representing an initially grown portion) of the GaN (gallium nitride) layer. By producing the above-mentioned state, dislocations generated in the central portion of the unit cell 5 can be bent at the facet surfaces (see FIG. 7) and are inhibited from progressing upward. As thickness of the grown film increases, the facet surface approaches the apex of the protrusion 20, and a growing surface becomes flat. From that point of time, the dislocation starts to grow upward from the apex of the protrusion 20. Because the facet surfaces formed during the above-mentioned growth process tend to define a hexagon when viewed in the direction perpendicular to the surface of the nitride semiconductor layer 14. Therefore, the layout of the protrusions 20 in the unit cell 5 is desired to be hexagonal and is most desirably regular hexagonal.

The growing surface becomes flat in a region where a height from a flat plane (flat region including no protrusions) of the growth substrate 10 exceeds a little the height of the protrusion 20. In the related art, the non-doped layer and the N-type layer are each deposited thickly to improve crystallinity. However, if a thickness of the growing film is increased after the flattening of the growing surface, a probability of the dislocation shifting horizontally from the apex of the protrusion 20 increases. In this embodiment, therefore, a film thickness deposited after the flattening of the growing surface is minimized. More specifically, a thickness T1 (see FIG. 7) of the gallium nitride layer from the height at the apex of the protrusions 20 to a start point of the V pit 40 is desired to be the mesa size or less and is more desirably half of the mesa size or less. This results in that a thickness from the flat surface of the growth substrate 10 to a surface of the N-type layer 11 is about two to three times the height of the protrusion 20 and is about half the thickness of the nitride semiconductor layer 14 in the related art.

After the flattening of the growing surface, the process is quickly changed to growth of N-type GaN. After a predetermined thickness of the N-type GaN has grown, formation of the V pit 40 is started. A most general method of starting the formation of the V pit 40 is to lower a growth temperature. A method of forming the V pit, a method of improving crystallinity by forming a multilayer film including an InGaN layer in parallel to growth of the V pit, and a structure of the multilayer film are well known and hence are not described in detail here.

After the V pit 40 has grown to a certain size, a multiple quantum well layer serving as the light emitting layer 12 is formed, and the P-type layer 13 is further formed. Within the V pit, the multiple quantum well layer is formed on its inner wall, whose thickness is thinner than one on a flat portion. The inside of the V pit is finally filled with the P-type layer. In this embodiment, as illustrated in FIG. 7, the V pit 40 is formed above the apex of the protrusion 20. In a plan view, as illustrated in FIG. 3B, the six V pits 40 are arranged along an outer periphery, and the region where any V pit is not present is formed at a center.

However, because the positions of the V pits are not exactly controllable as described above, there are cases in which the V pit is shifted horizontally from a predetermined position like a V pit A in FIG. 3B and in which the V pit is formed at a point deviated from the apex of the protrusion 20 like a V pit B or a V pit C. In most cases, however, it is possible to form such a layout that any V pit is not present in the central portion of the unit cell 5 and the V pits surround the central portion.

Returning to FIG. 4, after the growing of the nitride semiconductor layer 14, the P-electrode 23P is formed as illustrated in 4002 of FIG. 4. The P-electrode 23P is formed to cover the central portion of the unit cell, namely the region where any V pit 40 is not present. The P-electrode 23P may cover parts of the V pits 40. Then, as illustrated in 4003 of FIG. 4, a mesa portion 16 and a division groove 15 are formed by removing parts of the nitride semiconductor layer 14 around the P-electrode 23P with dry etching. At that time, parts of the divided V pits 40 remain at ends of the mesa portion 16, and the facets defining the V pits 40 remain in most parts around the mesa portion 16. The mesa portion 16 is one example of “a region of the nitride semiconductor layer” stated in Claims.

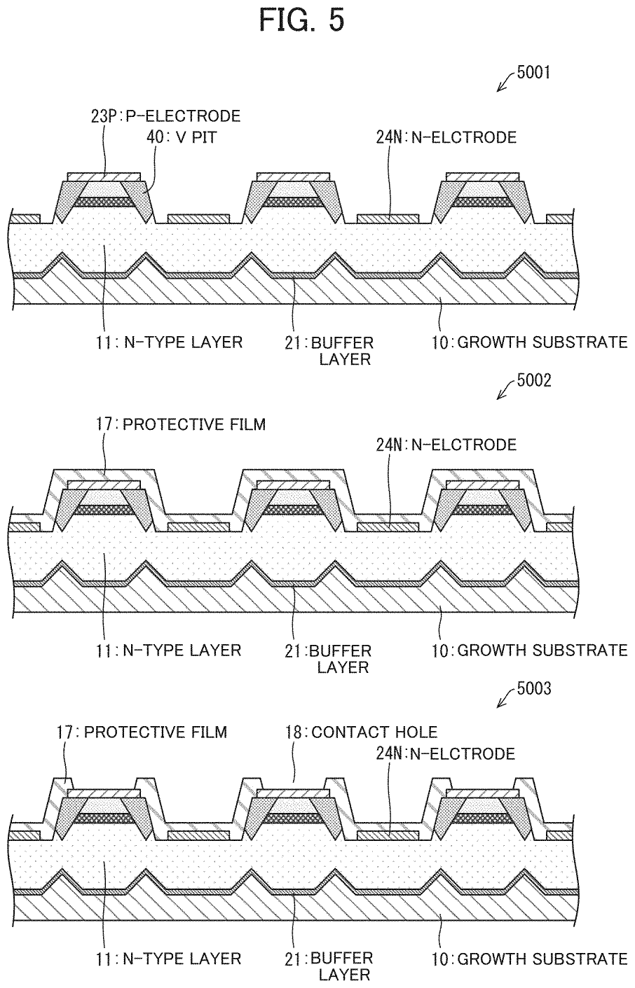

Then, as illustrated in 5001 of FIG. 5, the N-electrode 24N is formed at the bottom of the division groove 15. Then, as illustrated in 5002 of FIG. 5, a protective film 17 is formed. The protective film 17 is desired to be a transparent insulating film like a silicon oxide film. Then, as illustrated in 5003 of FIG. 5, a contact hole 18 is formed in the protective film 17 to make the P-electrode 23P exposed. Then, as illustrated in 6001 of FIG. 6, a connection electrode 19 is formed on the P-electrode 23P. Then, as illustrated in 6002 of FIG. 6, the growth substrate processed through the above-described steps upto 6001 of FIG. 6 is reversed upside down and is bonded to the driving circuit backplane 50. As a result, a P-drive electrode 51 arranged on a surface of the driving circuit backplane 50 and the connection electrode 19 are connected to each other, and a path allowing a current to flow from the driving circuit backplane 50 to the micro light emitting element 100 is formed. At the same time, although not illustrated, an N-drive electrode arranged on the surface of the driving circuit backplane 50 and the N-electrode 24N are also connected to each other. A filler 25 is introduced to fill a space between the drive circuit backplane and the micro light emitting elements. Then, as illustrated in 6003 of FIG. 6, the growth substrate 10 is peeled off and an upper surface of the N-type layer 11 is polished, whereby the micro light emitting element 100 is completed.

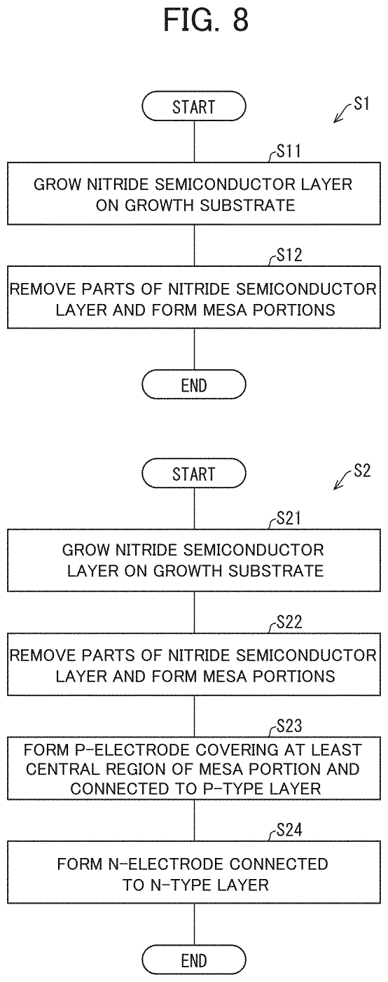

The above manufacturing method of the micro light emitting element 100 can also be explained as follows. The manufacturing method of the micro light emitting element 100 includes the following steps as illustrated in a flow S1 of FIG. 8. More specifically, in step S11, the nitride semiconductor layer 14 is grown on the growth substrate 10. Then, in step S12, parts of the nitride semiconductor layer 14 are removed, and the multiple mesa portions 16 are formed. In the manufacturing method according to this embodiment, the unit cells 5 each including the protrusion array in which the protrusions 20 are arranged at the positions corresponding to the vertexes of the polygon are arranged in the two-dimensional array on the surface of the growth substrate 10. Furthermore, the mesa portions 16 are each positioned in the central region of the protrusion array.

With the above-described manufacturing method, when viewed in the direction perpendicular to the surface of the nitride semiconductor layer 14, the multiple V pits 40 are arranged at the positions corresponding to the vertexes of the polygon in a one-to-one relation in the region of the nitride semiconductor layer 14. Therefore, any V pit 40 is not formed in the central region of the light emitting layer 12. Since that central region where any V pit 40 is not formed can be utilized as the light emitting region, reduction in the light emission efficiency caused by the V pits 40 can be suppressed. As a result, the micro light emitting element can be realized which is very small and which has high light emission efficiency.

Another manufacturing method of the micro light emitting element 100 includes the following steps. As illustrated in a flow S2 of FIG. 8, in step S21, the nitride semiconductor layer 14 is first grown on the growth substrate 10. The nitride semiconductor layer 14 includes a multilayer structure in which the N-type layer 11, the light emitting layer 12, and the P-type layer 13 are stacked. Then, in step S22, parts of the nitride semiconductor layer 14 are removed, and the multiple mesa portions 16 are formed. Each of the multiple mesa portions 16 includes the nitride semiconductor layer 14 (namely, the N-type layer 11, the light emitting layer 12, and the P-type layer 13). Furthermore, in step S23, for each of the mesa portions 16, the P-electrode is formed to cover at least the central region of the mesa portion 16 and to be connected to the P-type layer 13. Then, in step S24, the N-electrode 24N to be connected to the N-type layer 11 is formed.

The above-described manufacturing method can realize the micro light emitting element that is very small, that has high light emission efficiency, and that includes the nitride semiconductor layer including the N-type layer, the light emitting layer, and the P-type layer.

### Modification

The manufacturing method of the micro light emitting element 100 connected to the driving circuit backplane 50 has been described above with reference to FIGS. 4 to 6. However, individual micro light emitting elements 100 may be bonded to a transfer substrate instead of the driving circuit backplane 50 and, after peeling off the growth substrate 10 and separating the micro light emitting elements 100 into individual pieces, those micro light emitting elements 100 may be transferred to another driving circuit backplane 50 (although not illustrated).

### Advantageous Effects of First Embodiment

According to this embodiment, as described above, the multiple V pits 40 are arranged at the positions corresponding to the vertexes of the regular hexagon in the nitride semiconductor layer 14 of the micro light emitting element 100. Therefore, any V pit 40 is not formed in the region surrounded by the V pits 40. Since the region where any V pit 40 is not formed can be utilized as the light emitting region, reduction in the light emission efficiency due to the V pits 40 can be suppressed. As a result, the micro light emitting element can be realized which is very small and which has high light emission efficiency. In other words, it is possible to realize the micro light emitting element that is suitable for an image display element with high resolution, that has high brightness and low power consumption, and that is as small as a micron or submicron size.

In the related art, as illustrated in FIG. 14C, the protrusions are arrayed over the entire growth surface in a closest packed state with the protrusions arranged at vertexes of regular triangles each having one side of about 3 μm. A clear difference of protrusions between the related art and this embodiment is that this embodiment has an open space without a protrusion in the center of the protrusion array for this embodiment but the related art does not have. The open space may be as large as one protrusion or larger than one protrusion. In this embodiment, materials and equipment in the related art can be used just by changing the size and layout of the protrusions that are formed on the growth substrate in the related art. Therefore, no cost issues occur when those materials and equipment are applied to practical production of the micro light emitting element 100 according to this embodiment.

### Second Embodiment

### Structure of Micro Light Emitting Element 100a

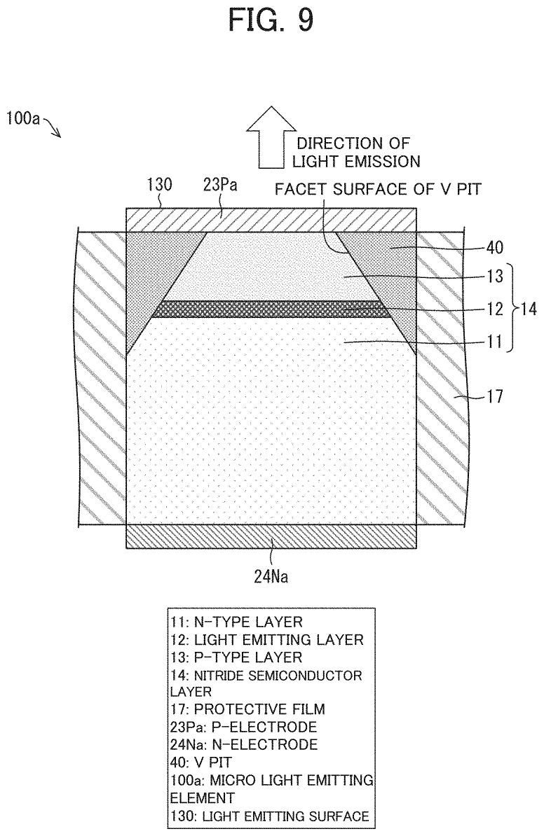

A structure and a manufacturing method of a micro light emitting element 100a according to a second embodiment of the present disclosure will be described below with reference to FIGS. 9 and 10 to 12. For convenience of explanation, members with the same functions as those in the above-described embodiment are denoted by the same reference signs, and description of those members is not repeated.

FIG. 9 is a schematic sectional view of the micro light emitting element 100a according to the second embodiment. While a light emitting surface 130 is arranged on the same side as the N-type layer 11 in the micro light emitting element 100 according to the first embodiment, the second embodiment is different from the first embodiment in that, as illustrated in FIG. 9, the P-type layer 13 is arranged on the same side as the light emitting surface 130. Stated in another way, while in the first embodiment an opening side of the V pit 40 (namely, a side where the V pit 40 has a larger diameter in a plan view) is arranged on a side closer to the driving circuit backplane 50, in the second embodiment the opening side of the V pit 40 is arranged on a side closer to the light emitting surface 130 in the micro light emitting element 100a.

As illustrated in FIG. 9, the nitride semiconductor layer 14 forming the micro light emitting element 100a is completely isolated from the adjacent micro light emitting element 100a by the protective film 17. Furthermore, the P-electrode 23Pa in this embodiment is desired to be a transparent electrode allowing light to pass therethrough because the emitted light passes through the P-electrode 23Pa.

### Manufacturing Method of Micro Light Emitting Element 100a

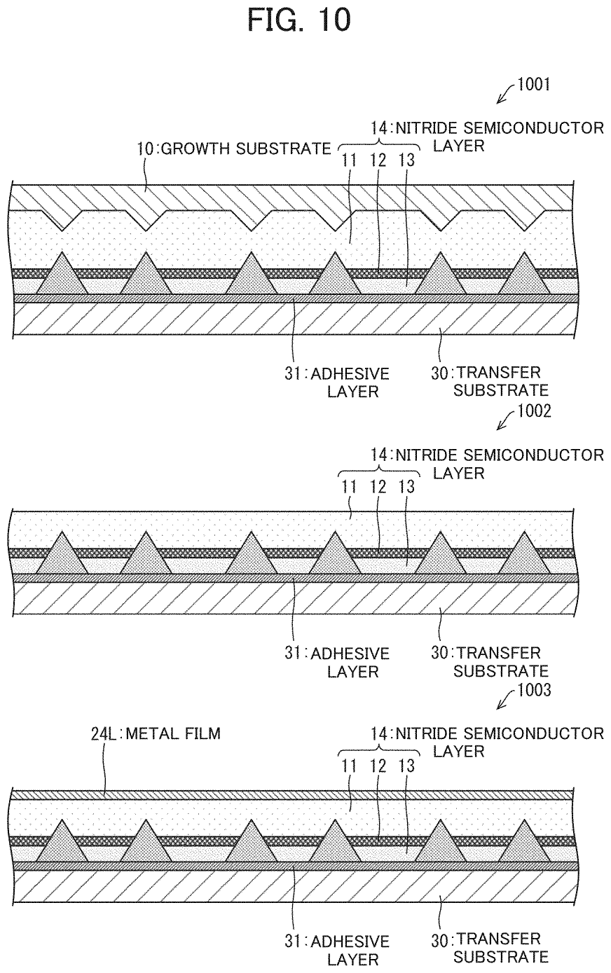

A manufacturing method of the micro light emitting element 100a will be described below with reference to FIG. 10 to 12. As in the first embodiment, the growth substrate 10 illustrated in FIG. 3A (or 4001 in FIG. 4) is used as a growth substrate to manufacture the micro light emitting element 100a. A step of growing the nitride semiconductor layer 14 on the growth substrate 10 is the same as the step described in the first embodiment.

After growing the nitride semiconductor layer 14 on the growth substrate 10, as illustrated in 1001 of FIG. 10, the growth substrate 10 is bonded at a side including the nitride semiconductor layer 14 to a transfer substrate 30 with an adhesive layer 31 interposed therebetween. Then, as illustrated in 1002 of FIG. 10, the growth substrate 10 is peeled off, the nitride semiconductor layer 14 is polished, and a thickness of the micro light emitting element 100a is adjusted to a value suitable for practical use.

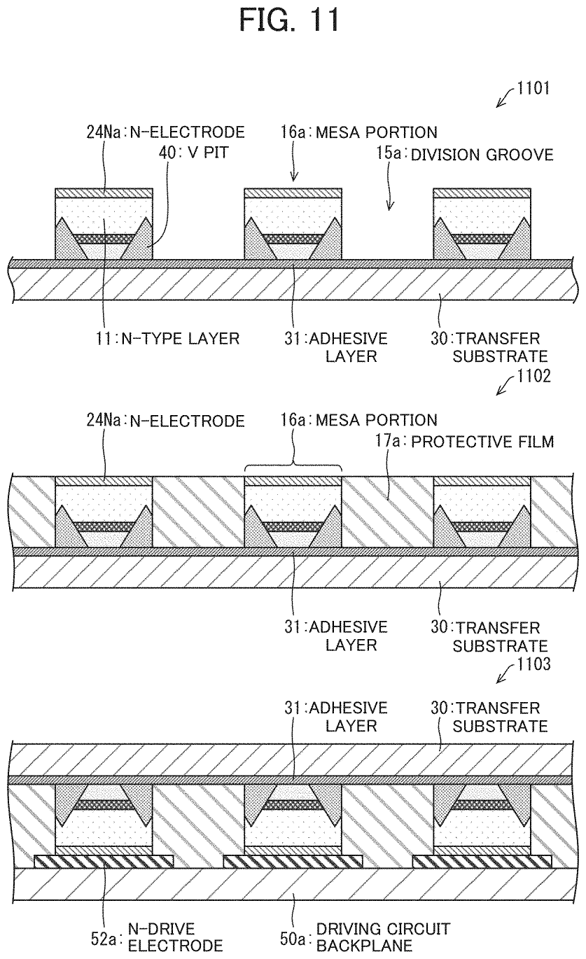

Then, as illustrated in 1003 of FIG. 10, a metal film 24L serving as an N-electrode is deposited. Then, as illustrated in 1101 of FIG. 11, the metal film 24L and the nitride semiconductor layer 14 are divided by photolithography and dry etching. In more detail, the metal film 24L and the nitride semiconductor layer 14 are divided by division grooves 15a into the individual mesa portions 16a for each of the micro light emitting elements 100a, and the metal film 24L is divided into the individual N-electrodes 24Na. As in the first embodiment, most parts of sidewalls of each mesa portion 16a are defined by cut surfaces of the V pits 40.

Then, as illustrated in 1102 of FIG. 11, the mesa portions 16a are covered with a protective film 17a, and the N-electrodes 24Na are made exposed. In 1102 of FIG. 11, the division grooves 15a are fully filled with the protective film 17a. Such a structure can be formed by depositing the thick protective film 17a and polishing the deposited protective film by CMP. However, the protective film 17a may be disposed to cover the surroundings of the mesa portions 16a including an upper side thereof, and the protective film 17a on the N-electrodes 24Na may be removed by photolithography and dry etching. As an alternative, it is also possible to divide the nitride semiconductor layer 14 before depositing the metal film 24L, to deposit the protective film 17a, to make the mesa portions 16a exposed, and thereafter to form the N-electrodes 24Na.

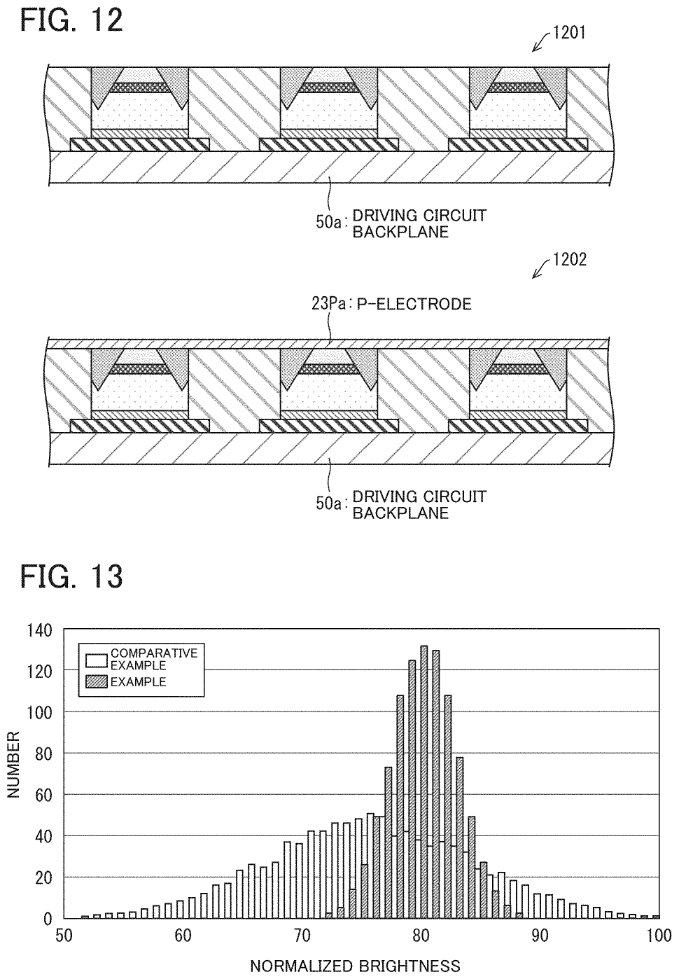

Then, as illustrated in 1103 of FIG. 11, the transfer substrate 30 is bonded at a side including the N-electrodes 24Na to a driving circuit backplane 50a. At that time, the N-electrodes 24Na and N-drive electrodes 52a arrayed on a surface of the driving circuit backplane 50a are connected to each other. Then, as illustrated in 1201 of FIG. 12, the transfer substrate 30 and the adhesive layer 31 are peeled off. Furthermore, as illustrated in 1202 of FIG. 12, a P-electrode 23Pa is deposited. A known technique can be used as a method of connecting the P-electrode 23Pa and a P-drive electrode (not illustrated) on the driving circuit backplane 50a, and hence description of the connecting method is omitted.

### Advantageous Effects of Second Embodiment

The second embodiment can also provide comparable advantageous effects to those obtained with the first embodiment. In the micro light emitting element 100a according to the second embodiment as well, the multiple V pits 40 are arranged at the positions corresponding to the vertexes of the regular hexagon in the region of the nitride semiconductor layer 14, and any V pit 40 is not formed in the region surrounded by the V pits 40. Since the region where any V pit 40 is not formed can be utilized as the light emitting region, reduction in the light emission efficiency due to the V pits 40 can be suppressed. As a result, the micro light emitting element can be realized which is very small and which has high light emission efficiency.

### Notes

The present disclosure is not limited to the above-described embodiments and can be variously modified within the scope defined in Claims. Embodiments obtained by combining the technical matters disclosed in the different embodiments as appropriate also fall within the technical scope of the present disclosure. In addition, novel technical features can be produced by combining the technical matters disclosed in the embodiments.

### Recapitulation

According to a first aspect of the disclosure, there is provided a micro light emitting element comprising a nitride semiconductor layer in which an N-type layer, a light emitting layer, and a P-type layer are stacked, wherein, viewing in a direction perpendicular to a surface of the nitride semiconductor layer, multiple V pits are arranged at positions corresponding to vertexes of a polygon in a one-to-one relation in a region of the nitride semiconductor layer.

With the feature described above, the multiple V pits are arranged at the positions corresponding to the vertexes of the polygon, and any V pit is not formed in a region surrounded by the V pits. Since the region where any V pit is not formed is utilized as the light emitting region, reduction in the light emission efficiency due to the V pits can be suppressed. As a result, the micro light emitting element can be realized which is very small and which has high light emission efficiency.

According to a second aspect of the disclosure, in the micro light emitting element according to the first aspect, viewing the light emitting layer in the direction perpendicular to the surface of the nitride semiconductor layer, ends of the light emitting layer may be in contact with facet surfaces of the multiple V pits.

With the feature described above, any V pit is not formed in a central portion of the nitride semiconductor layer in a plan view. As a result, the micro light emitting element can be realized which is very small and which has high light emission efficiency.

According to a third aspect of the disclosure, in the micro light emitting element according to the second aspect, viewing the light emitting layer in the direction perpendicular to the surface of the nitride semiconductor layer, the facet surfaces with which the ends of the light emitting layer are in contact may have a shape geometrically similar to the polygon.

With the feature described above, any V pit is not formed in the central portion of the nitride semiconductor layer in the plan view. As a result, the micro light emitting element can be realized which is very small and which has high light emission efficiency.

According to a fourth aspect of the disclosure, in the micro light emitting element according to any one of the first to third aspects, the polygon may be an n-sided polygon with n≥6 (n: an integer).

With the feature described above, the micro light emitting element can be realized which is very small and which has high light emission efficiency.

According to a fifth aspect of the disclosure, in the micro light emitting element according to the fourth aspect, the polygon may be a regular hexagon.

With the feature described above, the micro light emitting element can be most efficiently realized which is very small and which has high light emission efficiency.

According to a sixth aspect of the disclosure, there is provided a growth substrate on which a nitride semiconductor layer is to be grown, wherein unit cells each including a protrusion array in which protrusions are arranged at positions corresponding to vertexes of a polygon are arranged in a two-dimensional array on a surface of the growth substrate.

With the feature described above, the nitride semiconductor layer can be grown in a state not including any V pit in a central region of the polygon. Since that central region is basically utilized as the light emitting region, the micro light emitting element can be manufactured which is very small and which has high light emission efficiency.

According to a seventh aspect of the disclosure, in the growth substrate according to the sixth aspect, the polygon may be an n-sided polygon with n≥6 (n: an integer).

With the feature described above, the micro light emitting element can be manufactured which is very small and which has high light emission efficiency.

According to an eighth aspect of the disclosure, in the growth substrate according to the seventh aspect, the polygon may be a regular hexagon.

With the feature described above, the micro light emitting element can be most efficiently manufactured which is very small and which has high light emission efficiency.

According to a ninth aspect of the disclosure, there is provided a manufacturing method of a micro light emitting element, the manufacturing method including growing a nitride semiconductor layer on a growth substrate and forming multiple mesa portions by removing parts of the nitride semiconductor layer, wherein unit cells each including a protrusion array in which protrusions are arranged at positions corresponding to vertexes of a polygon are arranged in a two-dimensional array on a surface of the growth substrate, and the mesa portions are each formed in a central region of the protrusion array.

With the feature described above, it is possible to manufacture the micro light emitting element including the nitride semiconductor layer in which any V pit is not formed in a central region of the polygon. Since the light emitting region is formed principally in the above-mentioned central region, the micro light emitting element can be manufactured which is very small and which has high light emission efficiency.

According to a tenth aspect of the disclosure, in the manufacturing method of the micro light emitting element according to the ninth aspect, the nitride semiconductor layer may include a multilayer structure in which an N-type layer, a light emitting layer, and a P-type layer are stacked, and each of the multiple mesa portions may include the nitride semiconductor layer, and the manufacturing method may further include forming, for each of the mesa portions, a P-electrode that covers at least a central region of the mesa portion and that is connected to the P-type layer, and forming an N-electrode that is connected to the N-type layer.

With the feature described above, the micro light emitting element can be manufactured which is very small, which has high light emission efficiency, and which includes the nitride semiconductor layer including the N-type layer, the light emitting layer, and the P-type layer.

### Example

Example will be described below. The micro light emitting elements 100 described in the first embodiment were fabricated in accordance with the above-described manufacturing method. However, the micro light emitting elements 100 are very small and are difficult to evaluate individually. For that reason, after bonding the manufactured micro light emitting elements 100 to the driving circuit backplane 50, light emission intensities of the individual micro light emitting elements 100 were measured by accessing them with use of a circuit in the driving circuit backplane 50. The driving circuit backplane 50 used in the evaluation was able to operate for 352×198 pixels. The evaluation of brightness was performed on 900 or more among the total pixels.

The brightness was compared between Example, namely the micro light emitting elements 100 each using the nitride semiconductor layer 14 to which the first embodiment was applied, and Comparative Example, namely the micro light emitting elements each using the nitride semiconductor layer of the related art. Steps of forming the micro light emitting elements were the same between Example and Comparative Example.

The array pitch of the micro light emitting elements 100 (length of one side of the unit cell 5) in Example was 8.2 μm, and the length of one side of the mesa portion 16 (mesa size) was 2.5 μm. The emission wavelength was 450 nm. Each of the protrusions 20 had a conical shape with the height of 1.5 μm and the bottom surface diameter of 1.5 μm. The protrusion array had a regular hexagonal shape with the distance between opposing sides being 2.2 μm.

The micro light emitting elements according to Comparative Example had the same shape as the micro light emitting elements 100 according to Example and were manufactured by using the growth substrate including the closest-packed protrusions with the diameter of 3 μm and the height of 2 μm as illustrated in FIG. 14C.

FIG. 13 indicates a histogram of brightness distribution of the micro light emitting elements 100 according to Example and of the micro light emitting elements according to Comparative Example. The brightness is normalized with a maximum value obtained in samples of the nitride semiconductor layers in Comparative Example being 100. The brightness of the micro light emitting elements according to the related art is represented by a hollow bar, and the brightness of the micro light emitting elements 100 according to Example is represented by a solid black bar.

As seen from FIG. 13, the micro light emitting elements 100 according to Example can realize a much narrower brightness distribution than those according to Comparative Example. The standard deviation of the brightness distribution is 8.9 in Comparative Example, but it is 2.8 in this Example. Thus, the standard deviation in Example is reduced to about ⅓. Because the nitride semiconductor layers in the micro light emitting elements 100 according to Example are thinner than in Comparative Example, a maximum characteristic value in Example is slightly lower than that in Comparative Example. However, a very great effect of reducing a variation in the brightness distribution is obtained in Example. Furthermore, reduction in the thickness of the nitride semiconductor layers leads to a shorter epitaxial growth time and hence serves as a plus factor in reducing the cost.

Thus, it has been found that the micro light emitting elements 100 with a small variation in the light emission intensity can be formed by arranging, in each of the unit cells 5, the protrusions 20 at positions corresponding to vertexes of a polygon, by growing the nitride semiconductor layer 14 such that the nitride semiconductor layer 14 in a central portion of the polygon is formed as the mesa portion 16 in each of the micro light emitting elements 100, and by utilizing the central region of the mesa portion 16 as the light emitting region 3.

While there have been described what are at present considered to be certain embodiments of the invention, it will be understood that various modifications may be made thereto, and it is intended that the appended claims cover all such modifications as fall within the true spirit and scope of the invention.

It should be understood by those skilled in the art that various modifications, combinations, sub-combinations and alterations may occur depending on design requirements and other factors insofar as they are within the scope of the appended claims or the equivalents thereof.

What is claimed is:

1. A micro light emitting element comprising:
a nitride semiconductor layer in which an N-type layer, a light emitting layer, and a P-type layer are stacked,
wherein, viewing in a direction perpendicular to a surface of the nitride semiconductor layer, multiple V pits are arranged at positions corresponding to vertexes of a polygon in a one-to-one relation in a region of the nitride semiconductor layer.

2. The micro light emitting element according to claim wherein a central region of the polygon is a principal light emitting region.

3. The micro light emitting element according to claim wherein the multiple V pits are divided by division grooves defining the region of the nitride semiconductor layer.

4. The micro light emitting element according to claim 1, wherein the P-type layer is arranged on a light emitting surface side of the micro light emitting element.

5. The micro light emitting element according to claim 1, wherein the N-type layer is arranged on a light emitting surface side of the micro light emitting element.

6. The micro light emitting element according to claim 1, wherein, viewing the light emitting layer in the direction perpendicular to the surface of the nitride semiconductor layer, ends of the light emitting layer are in contact with facet surfaces of the multiple V pits.

7. The micro light emitting element according to claim 6, where n, viewing in the direction perpendicular to the surface of the nitride semiconductor layer, the facet surfaces with which the ends of the light emitting layer are in contact have a shape geometrically similar to the polygon.

8. The micro light emitting element according to claim 1, wherein the polygon is an n-sided polygon with n≥6 (n: an integer).

9. The micro light emitting element according to claim 8, wherein the polygon is a regular hexagon.

10. A growth substrate on which a nitride semiconductor layer is to be grown,
wherein unit cells each including a protrusion array in which protrusions are arranged at positions corresponding to vertexes of a polygon are arranged in a two-dimensional array on a surface of the growth substrate.

11. The growth substrate according to claim 10, wherein the polygon is an n-sided polygon with n≥6 an integer).

12. The growth substrate according to claim 11, wherein the polygon is a regular hexagon.

13. An image display element comprising:
multiple micro light emitting elements arranged in an array pattern on a driving circuit backplane, the driving circuit backplane including a driving circuit that supplies currents to the micro light emitting elements and that controls emission of light,
each of the micro light emitting elements comprising a nitride semiconductor layer in which an N-type layer, a light emitting layer, and a P-type layer are stacked,
wherein, viewing in a direction perpendicular to a surface of the nitride semiconductor layer, multiple V pits are arranged at positions corresponding to vertexes of a polygon in a one-to-one relation in a region of the nitride semiconductor layer.

14. The image splay element according to claim 13, wherein the nitride semiconductor layers included in the micro light emitting elements are divided by division grooves for each of the multiple micro light emitting elements.

15. The image display element according to claim 13, wherein N-electrodes connected to the N-type layers of the multiple micro light emitting elements are arranged in a one-to-one relation to the multiple micro light emitting elements.

16. The image display element according to claim 13, wherein the N-type layers included in the multiple micro light emitting elements are connected to each other.

17. The image splay element according to claim 13, wherein N-electrodes connected to the N-type layers of the multiple micro light emitting elements are each arranged between adjacent two of the multiple micro light emitting elements.
